(19) United States
(12) Patent Application Publication
(10) Pub. No.: US 2011/0032015 A1
(43) Pub. Date: Feb. 10, 2011

(54) SYSTEMS AND METHODS FOR CLOCK CORRECTION

(75) Inventors: Jinxia Bai, San Diego, CA (US); Linbo Li, San Diego, CA (US)

Correspondence Address: McDermott Will & Emery LLP, 600 13th Street, NW, Washington, DC, 20005-3096, US

(73) Assignee: QUALCOMM Incorporated, San Diego, CA (US)

(21) Appl. No.: 12/793,546

(22) Filed: Jun. 3, 2010

Related U.S. Application Data
(60) Provisional application No. 61/232,738, filed on Aug. 10, 2009.

(51) Int. Cl. H03L 7/00

(52) U.S. Cl. 327/162

(57) ABSTRACT

A method, apparatus and system for correcting different clock domains are disclosed. The disclosed implementations correct a second clock domain by making reference to a resampling filter, or similar device, used to correct a first clock domain. The implementations thereby facilitate clock correction using fewer or a different variety of elements.

### RELATED APPLICATIONS

The present Application claims priority to U.S. Provisional Application No. 61/232,738 entitled “LOGIC FOR SYNCHRONIZATION OF DIFFERENT CLOCK DOMAINS WITH RESAMPLING FILTER” filed Aug. 10, 2009, which is hereby expressly incorporated by reference in its entirety.

### TECHNICAL FIELD

The present embodiments relate to clocked systems, and in particular, to methods and systems for correcting clocks in a clocked system.

### BACKGROUND

Mobile devices are rapidly decreasing in size and cost. This trend generally necessitates that the number of components within the mobile device be reduced, or that the component arrangement be altered, such as by reducing component size, to accommodate more efficient designs. These reductions often decrease the manufacturing cost of the mobile device, while also reducing the weight of the mobile device. This is particularly important in mobile telephone systems, where a user may be holding the mobile device in an elevated position for long periods of time.

Mobile devices typically utilize multiple clocks, operating at different frequencies. This may be necessary as different circuits within the device may be designed to operate at different clock frequencies. By way of illustration, a microprocessor may use a different clock frequency than the transceiver circuits. Furthermore, certain operations, such as demultiplexing or decoding, may utilize a plurality of clocks, each at a different frequency. If the clocks are not properly corrected, inter-carrier interference (ICI) may result, as data is improperly mixed from across frequency channels. Further undesirable behavior may result from clock domain frequency errors.

### SUMMARY

In some implementations, an electronic system for clock correction is disclosed comprising: a first correction module, configured to modify samples of a first clock, where the first clock is associated with a first target frequency and has a first actual frequency, so that a difference between the first actual frequency and the first target frequency is reduced. The system may also comprise a second correction module, configured to modify samples of a second clock, wherein the second clock is associated with a second target frequency and has a second actual frequency, based on the modifications of the first correction module, such that a difference between the second actual frequency and the second target frequency is reduced.

In certain implementations, the modifications of the first correction module do not depend on the ratio of the first and second target frequencies. In some implementations, the modifications of the second correction module may depend at least in part on the ratio of the first and second target frequencies. Modifications of the second correction module may comprise at least one of insertions and skips. The first correction module may comprise a resampling filter. In some implementations, at least one of the first and second correction modules may comprise a processor executing software.

In some implementations, to modify samples of a second clock may comprise determining if a number of modified samples from the first clock is an integer multiple of a modification threshold, and if so, to insert or skip samples from the second clock. The modification threshold may be determined in part by a number of states in a digital circuit. In some implementations, the ratio of the frequency of the first clock to the frequency of the second clock is P/Q, where P and Q are the smallest positive integers capable of expressing the ratio, and at least Q states of the digital circuit perform modifications.

Certain implementations disclose an electronic system for clock correction comprising: a first and second series of means for indicating a clock cycle; a first means for correction configured to modify the first series of cycle indication means such that a difference between a first actual frequency and a first target frequency is reduced, a second means for correction configured to modify the second series of cycle indication means such that a difference between a second actual frequency and a second target frequency is reduced.

In some implementations, the cycle indication means may comprise clock samples. The first correction means' modifications may not depend on the ratio of the first and second target frequencies. In certain implementations, the second correction means' modifications may depend at least in part on the ratio of the first and second target frequencies. In some implementations, the second correction means' modifications may comprise at least one of insertions and skips. In some implementations, the first correction means may comprise a resampling filter. In certain implementations, at least one of the first and second correction means may comprise a processor executing software.

In certain implementations, to modify the second series of cycle indication means may comprise determining if a number of modifications of the first series of cycle indication means by the first correction means is an integer multiple of a modification threshold, and if so, inserting or skipping cycle indication means in the second series. The modification threshold is determined in part by a number of states in a digital circuit. In certain implementations, the ratio of the frequency of the first clock to the frequency of the second clock is P/Q, where P and Q are the smallest positive integers capable of expressing the ratio, and at least Q states of the digital circuit perform modifications.

Some implementations comprise a method for correcting a second clock based on the corrections of a first clock comprising: performing the following steps on at least one electronic device: determining if the number of modified samples from the first clock is an integer multiple of a modification threshold, and if so, modifying the second clock. The modification threshold can be determined in part by a number of states in a digital circuit. The number of at least some of the digital circuit's states can be determined based on the ratio of the first clock's frequency and the second clock's frequency.

In some implementations, the ratio of the frequency of the first clock to the frequency of the second clock is P/Q, where P and Q are the smallest positive integers capable of expressing the ratio, and at least Q states of the digital circuit perform modifications. The number of modified samples from the first clock may not depend on the ratio of the target frequency of the first clock and the target frequency of the second clock.

The modified samples may comprise at least one of insertions and skips. In some implementations, the corrections of the first clock may be generated by a resampling filter. The electronic device may comprise a processor executing software. In certain implementations, modifying the second clock may comprise inserting or skipping samples.

Certain implementations disclose a computer-readable storage medium in communication with a computer processor comprising a computer program configured to perform a process comprising: determining if the number of modified samples from a first clock is an integer multiple of a modification threshold, and if so, modifying a second clock. The modification threshold may be determined in part by a number of states in a finite state machine. The number of at least some of the finite state machine's states may be determined based on the ratio of the first clock's frequency and the second clock's frequency. In certain implementations, the ratio of the frequency of the first clock to the frequency of the second clock is P/Q, where P and Q are the smallest positive integers capable of expressing the ratio, and at least Q states of the finite state machine perform modifications. The number of modified samples from the first clock may not depend on the ratio of the target frequency of the first clock and the target frequency of the second clock. The modified samples may comprise at least one of insertions and skips. In some implementations, the corrections of the first clock are generated by a resampling filter. Modifying the second clock may comprise inserting or skipping samples.

Details of one or more implementations of the subject matter described in this specification are set forth in the accompanying drawings and the description below. Other features, aspects, and advantages will become apparent from the description, the drawings, and the claims.

### BRIEF DESCRIPTION OF THE DRAWINGS

The disclosed aspects will hereinafter be described in conjunction with the appended drawings, provided to illustrate and not to limit the disclosed aspects, wherein like designations denote the elements.

FIG. 1 is an abstract diagram of one possible device which may employ certain embodiments as part of its clock operations.

FIG. 2 is a high-level block diagram of an example mobile system with different clock domains derived from a primary clock implementing certain embodiments.

FIG. 3 illustrates an example finite state machine configured to provide clock correction via a particular embodiment.

FIG. 4 is a process flow diagram depicting certain of the operations of pseudo-code listing 1.

FIG. 5 is a process flow diagram depicting certain of the operations of pseudo-code listing 2.

### DETAILED DESCRIPTION

Implementations disclosed herein provide systems, methods and apparatus for efficient clock correction. In an example implementation, a clock correction system and method are configured to monitor corrections made to a first clock channel, and proportionally generate corrections for a second clock channel. Particularly, the system and method account for the relative difference in frequency of the two clock systems and then manipulate the signals of the second clock to achieve the proper frequency. One skilled in the art will recognize that this correction system can be implemented in hardware, software, firmware, or any combination thereof.

In the following description, specific details are given to provide a thorough understanding of the examples. However, it will be understood by one of ordinary skill in the art that the examples may be practiced without these specific details. For example, electrical components/devices may be shown in block diagrams in order not to obscure the examples in unnecessary detail. In other instances, such components, other structures and techniques may be shown in detail to further explain the examples.

It is also noted that the examples may be described as a process, which is depicted as a flowchart, a flow diagram, a finite state diagram, a structure diagram, or a block diagram. Although a flowchart may describe the operations as a sequential process, many of the operations can be performed in parallel, or concurrently, and the process can be repeated. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those having skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Further, while, for clarity, the examples below may refer to correction between two clocks, more than two clocks may be corrected using techniques described herein.

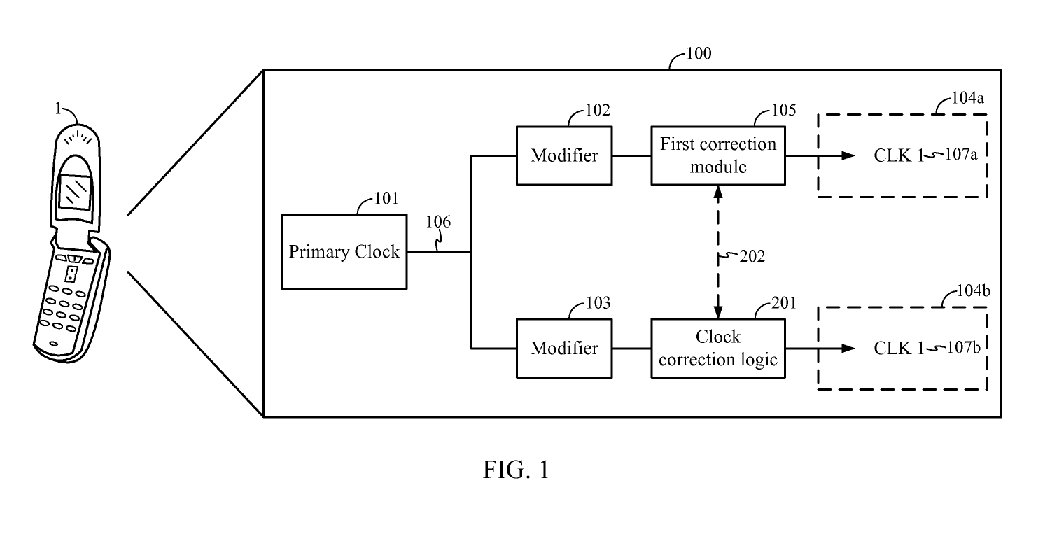

FIG. 1 depicts one possible electronic device 1 comprising clock operations 100. Certain implementations contemplate two or more clock domains derived from a source clock (e.g., a primary clock). To reduce the overall cost of a mobile device 1, or to satisfy certain design criterion, it may be desirable to utilize a fixed frequency crystal oscillator (XO), instead of a more expensive temperature compensated crystal oscillator (TCXO). However, the fixed frequency crystal oscillator may be significantly less temperature resistant, and consequently, more prone to error, than a temperature compensated crystal oscillator. When a clock derived from the fixed frequency crystal oscillator is used for analog to digital sampling, the resulting data may be distorted and degraded at certain temperatures. Where the crystal oscillator serves as a primary clock from which secondary clocks are derived, the errors may propagate to other operations in the device and consequently may create wide scale disruption. In some instances, it may not be possible to correct the primary clock directly and the secondary clocks derived from the primary clock need be corrected individually.

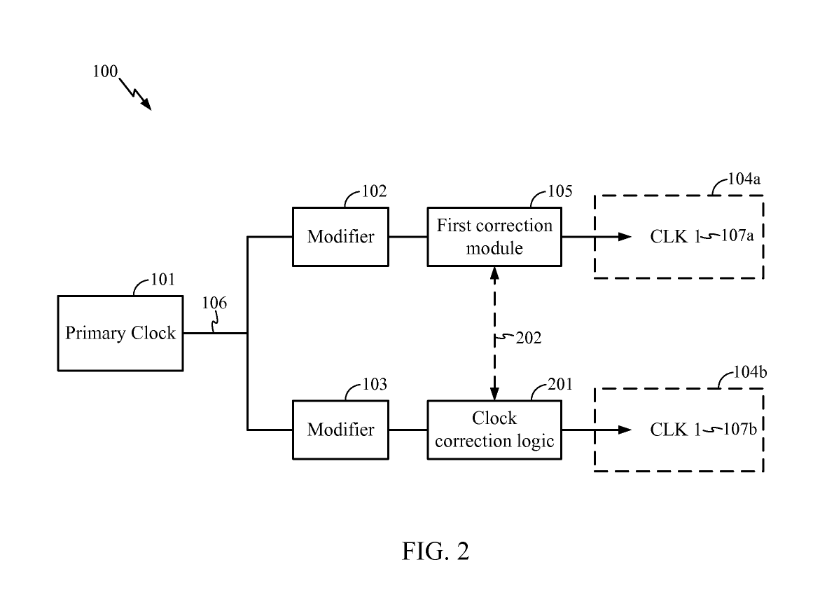

FIG. 2 illustrates a high-level block diagram of a mobile-system 100 with two different clock domains 104a, 104b derived from a source clock 101 (which may be a primary clock). Such a system may appear, for example, in a baseband digital filter. A clock domain, 104a, 104b refers to a particular clock frequency (e.g., CLK1 107A or CLK2 107B) used to clock one or more components. The primary clock 101 may be generated from a crystal oscillator (e.g., a fixed frequency crystal oscillator), subject to error, perhaps as a result of overheating. The output from the clock 101 is received, in this example, at least two modification systems 102 and 103. These modification systems 102 and 103 may multiply or divide the primary clock 101 to generate one or more secondary clocks, CLK1 107A or CLK2 107B, at a greater or reduced frequency (e.g., in a digital circuit they may be digital dividers or gates). For example, the clocks may be derived from the same phase locked loop coupled to a crystal. Naturally, errors in the primary clock 101 are propagated through to the secondary clocks CLK1 107A or CLK2 107B. Further, skew may be introduced into CLK1 107A or CLK2 107B after they are generated. Thus, CLK1 107A or CLK2 107B may each have a “desired” or target corrected frequency at which they are intended to operate, but in reality may function instead at an “actual” or uncorrected frequency. A given clock may be corrected by reducing the difference between the “actual” and “desired” or target frequency. In some implementations, a first correction module 105 may perform this correction. In some implementations, the first correction module 105 comprises a resampling filter. Although a resampling filter is discussed herein, other correction devices and techniques may be readily substituted.

An example resampling filter device may upsample the signal by a first amount, and then downsample the signal to a desired/target output clock frequency. Other filters may take different forms. By way of example, another resampler device may perform a digital to analog conversion and then an analog to digital conversion. During the process of conversion it is possible that the first correction module 105 may additionally serve the purpose of modification system 102, in deriving CLK1 107A from the primary clock 101. Despite the particular form the component serving the resampling function may take, present implementations contemplate the component skipping/removing or inserting samples (e.g., pulses) into a clock, such as CLK1 107A, in order to achieve the desired/target clock frequency. Although certain implementations refer to a clock “sample” for indicating a clock cycle, one would readily recognize other periodic divisions that may be used as well.

The resampling filter's corrections may not depend on the ratio of the desired/target frequencies of clocks CLK1 107A or CLK2 107B. That is, the modifications of the first correction module 105, may not depend on the ratio of the first and second desired/target frequencies of CLK1 107A or CLK2 107B. Although discussed here as being a resampling filter in some implementations, one having skill in the art will readily recognize a number of independent correction modules which could be used for first correction module 105, such as correction software implemented using a processor.

The skipping or inserting process may serve to correct the clock or to convert the clock to a proper secondary frequency (the “corrected” or “desired” frequency). Optionally, the process can be configured to ensure that there are no more and no less output samples in either clock domain than are desired for the proper frequency. Furthermore, in systems where the first clock domain 104a is derived from the same source as the second clock domain 104b, certain implementations ensure that equivalent clock correction is performed for both domains. For example, placing resampling filters in the pipeline for each clock domain, may result in inefficient use of space and hardware, and may not guarantee that the corrections for the first clock domain are commensurate with corrections for the second.

FIG. 2 also depicts clock correction logic module 201's operation in conjunction with the first correction module 105. The clock correction logic 201 is in communication, via connection 202, with the first correction module 105 such that the clock correction logic 201 is aware of “skips” or “inserts” generated by the first correction module 105. The clock correction logic 201 in some implementations may alternatively infer the skipping or insertion by comparison with the output clock signal CLK1 107A and primary clock 101. Clock correction logic module 201 modifies incoming primary clock 101 samples based on modifications made by first correction module 105 to generate a corrected CLK2 107B.

In some implementations, separate clock correction logic modules are optionally inserted at each clock domain 104a, 104b or in each of a plurality of domains (but not necessarily all domains). Each of the correction modules optionally refers to a single resampling filter, although certain applications may achieve better results if more than one filter is used and the correction modules are grouped together with their respective filters. Certain other implementations utilize a central correction module, able to dynamically adapt over time to provide proper corrections for a plurality of clock domains. Such a system would perform the correction methods described herein for a single clock domain, for multiple clock domains.

### Clock Correction Methodology

Assume the first clock CLK1 107A is to have a modified, desired, or target frequency, denoted FP. CLK2 107B is to similarly have a target frequency FQ different from FP. The ratio of the frequencies between the first clock CLK1 107A and the second CLK2 107B would therefore be FP/FQ. The ratio FP/FQ is represented by P/Q where P and Q are the smallest positive integers capable of representing FP/FQ (that is, if FP/FQ=1.5, then P=3, Q=2). Thus, if P were greater than Q, certain implementations recognize that when a resampling operation causes P clock cycles to be skipped or inserted in the CLK1 domain, Q clock cycles should be skipped or inserted in the CLK2 domain. That is, a commensurate number of modifications are to be performed once a modification threshold, or some multiple thereof, is reached. The resampling operations can be appropriately spaced in accordance with frequency FQ. This spacing may be a regular, substantially equal spacing, or the spacing may be aperiodic, depending on the design of the CLK2 domain. Two illustrative implementations wherein resampling operations are assumed to be distributed substantially uniformly in the second clock domain are described below.

Frequency FP may be either greater or less than frequency FQ. Pseudo-code Listing 1 (PCL1) outlines an implementation where P is greater than Q and Pseudo-code Listing 2 (PCL2) outlines an implementation where P is less than Q. For ease of comprehension, “skipping” or “removal” operations are included in both listings (e.g., by the function skipClk2( )), but one would readily understand that “insertions” could be performed in the same or similar manner.

Pseudo-Code Listing 1 (PCL1)

| | |
|---|---|
| (1) | if(P/Q > 1){ |
| (2) | k = 1; |
| (3) | skip_cnt = 1; |
| (4) | while(CLK1 cycles){ |
| (5) | if(clk1 skipped this cycle){ |
| (6) | skip_cnt++; |
| (7) | if(skip_cnt == P + 1) |
| (8) | skip_cnt = 1; |
| (9) | } |
| (10) | if(skip_cnt == Ceiling(k * P / Q) ){ |
| (11) | skipClk2( ); |
| (12) | k++; |
| (13) | if(k == Q + 1) |
| (14) | k = 1; |
| (15) | } |
| (16) | } |

As mentioned, PCL1 refers to an instance where P is greater than Q as described at line (1). At lines (2) and (3) the values k and skip_cnt are initialized to 1. k represents a counter used to update the modification threshold value at which CLK2 is skipped. skip_cnt is a counter used to monitor skipping of CLK1. As indicated at line (4) the logic monitors each cycle operated upon by the resampler when generating CLK1. If the resampler performs a skipping operation this cycle (5) the logic updates various counters (6)-(8). Particularly, skip_cnt is incremented (6) and then compared with P+1 (7). If skip_cnt has exceeded P, then the counter is reset to 1 (8).

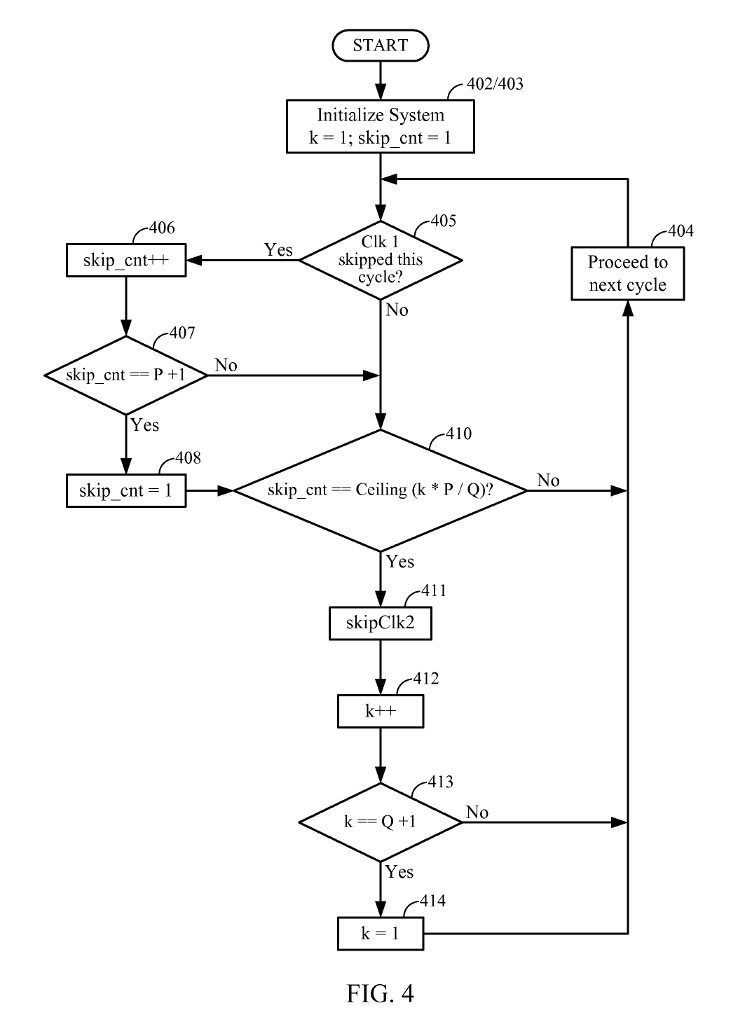

Each cycle, the skip_cnt is also compared with the ceiling of (k*P/Q) (10) (where “ceiling” refers to the next largest integer value when the value is a non-integer (e.g., 3.4 would become 4). This threshold, i.e. a modification threshold, establishes the timing conditions based on the relative frequencies of the two clock domains. When skip_cnt has reached this threshold, CLK2 is skipped (11) and the counter k is incremented (12). Similar to skip_cnt's monitoring with respect to P (7), k is also reset when it exceeds Q (13) and (14). The resulting CLK2 therefore receives corrections proportionally to corrections made in CLK1. The corrections can be uniformly distributed, although in some instances they need not be. The operations of PCL1 are reflected in the process flow diagram of FIG. 4, where each of lines (1), (2), (3), etc. in the code listing correspond to each of 401, 402, 403, etc. in the figure where applicable.

Pseudo-Code Listing 2 (PCL2)

| | |
|---|---|
| (1) | if(P/Q < 1){ |
| (2) | k = 1; |
| (3) | skip_cnt = 1; |
| (4) | While(CLK1 cycles){ |
| (5) | if(clk1 skipped this cycle){ |
| (6) | k++; |
| (7) | if(k == P + 1) |
| (8) | {k = 1;} |
| (9) | for(int i = 0; i < Ceiling(k*Q/P)-CEILING((k-1)*Q/P); i++) |
| (10) | skipClk2( ); |
| (11) | } |
| (12) | } |

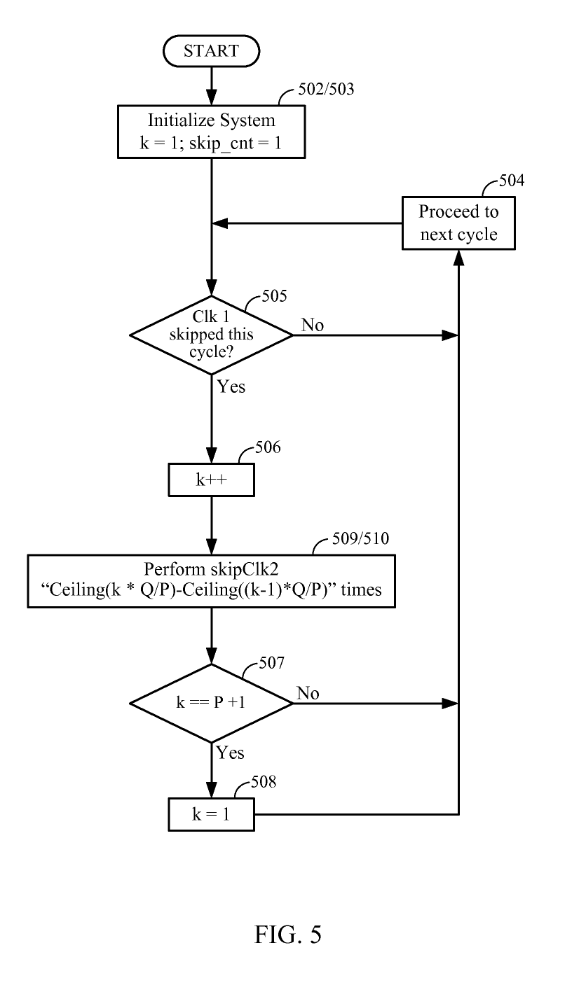

PCL2 describes operations when P is less than Q (1). As in PCL1, k and skip_cnt are initialized to 1 (2) and (3) and the logic is applied through each CLK1 cycle (4). When CLK1 is skipped (5), k is incremented (6). The logic also checks if k has met its threshold exceeding P (7). When the threshold is met, k is reset to 1 (8) and the logic performs each (9) of the modifications (10) necessary to maintain proportional corrections between CLK1 and CLK2. The number of corrections, in this example, is determined by the difference between the preceding counter values (e.g., Ceiling(k*Q/P)−Ceiling((k−1)*Q/P)). In this manner, CLK2 is modified appropriately for each of the CLK1 modifications in proportion to the relative frequencies. The operations of PCL2 are reflected in the process flow diagram of FIG. 5, where each of lines (1), (2), (3), etc. in the code listing correspond to each of 501, 502, 503, etc. in the figure where applicable.

### Clock Correction in Hardware

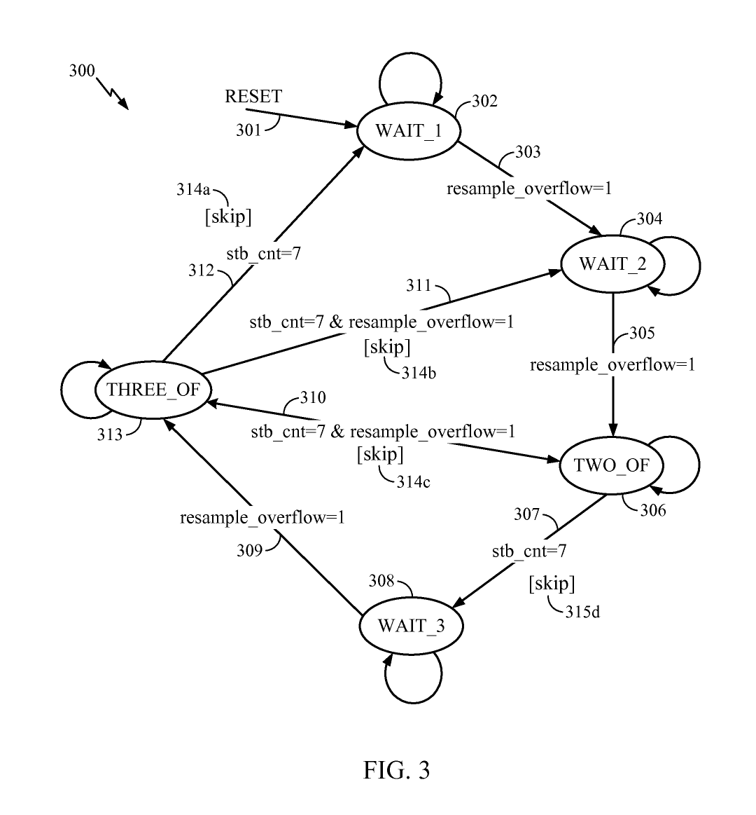

While for the purposes of explanation, PCL1 and PCL2 make reference to numerous variables and threshold calculations, one having skill in the art will readily recognize that the disclosed implementation readily lends itself to hardware or firmware implementations, where thresholds may be hardcoded, or appear implicitly in the design structure. For example, FIG. 3 illustrates the finite state machine (FSM) diagram of an example hardware implementation where P=3 and Q=2 (say, when FP is 12 MHz, and FQ is 8 MHz). In some implementations, each “correct” CLK1 cycle will have 3 pulses. A stretched, “incorrect” CLK1 cycle may have a fourth pulse. The resampling filter 105 from FIGS. 1 and 2 may correct by skipping, or removing, the fourth sample and the overflow can be indicated by the resampler flag “resample_overflow.” As illustrated in the FSM, the system is reset 301, to begin in state WAIT_1. The resample_overflow flag is reset to 0 after each transition in which it was raised. That is, if raised in state WAIT_2 for example, after transition 305 resample_overflow will remain low until the next incorrect cycle.

The goal of the hardware implementation is to ensure two skip/removal operations (314a-d) for every three resample_overflow (303, 305, 309, 310, 311) occurrences. In some implementations, it is preferable to insert or remove only at the end of a cycle. In this example, an 8 Mhz clock is assumed for FQ, and samples may be inserted or removed at the end of the cycle (stb_cnt=7).

The example finite state machine (FSM) of FIG. 3 comprises three separate “wait” states (302, 304, 308), and two operation states, 306 and 313. With reference to PCL1, the number of “wait” states, in combination with resample_overflow serves the function of lines (5)-(8). That is, increments in skip_cnt are reflected by the number of states traversed. “Wait” states are used to accrue enough resample overflows before another skip. Thus, WAIT_1 and WAIT_2 ensure the accumulation of two resample_overflows 303 and 305 before the first skip 314c or 314d. Thus, the states are a hard-coded relation of the condition skip_cnt=Ceiling(k*P/Q)=2 (when k=1). The term “k” itself, is implicit in the selection of states. The transition 310 is made available at TWO OF, as is the transition 311 at THREE_OF to avoid accruing additional resample_overflows should they occur, before the end of the second clock's cycle (stb_cnt=7). In the event the second clock cycle finishes before the next resample_overflow, transitions 307 and 312 are provided, so that the system will not omit an insertion or skipping operation before again counting resample_overflows.

Thus, one can verify that regardless of the path taken, for every three instances in which the resample_overflow is raised, two skips occur. For example, transitioning along edges 303, 305, 310, there have been three resample overflows and one skip. Any transition from this state (via arcs 311 or 312) will result in another skip and the beginning of a new cycle. The FSM therefore incorporates the hardcoded values of Ceiling(k*P/Q) (2) and (3), (see also (13) of PCL1) into its structure and ensures proper relative corrections between the two clocks.

One skilled in the art will readily recognize variations on this implementation, as the methods of PCL1 and PCL2 readily lend themselves to a variety of hardware implementations. This FSM also can be generalized by adding additional states and transitions.

The foregoing implementations may optionally be used in communication devices, such as a cellular phone, a forward-link only (FLO) device, other mobile terminal, a base station, or other device, to provide clock correction. By way of further example, the foregoing implementations may be used in a digital filter, such as a baseband digital filter.

Advantageously, the foregoing techniques can enable relatively lower cost components to be used while still providing the needed performance. For example, optionally, a fixed frequency crystal oscillator can be used to generate clocks, instead of a more expensive temperature compensated voltage controlled crystal oscillator, which may be conventionally used for such application.

Those having skill in the art will further appreciate that the various illustrative logical blocks, modules, circuits, and algorithm steps described in connection with the implementations disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the implementations disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the implementations disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of non-transitory storage medium known in the art. An exemplary computer-readable storage medium is coupled to the processor such the processor can read information from, and write information to, the computer-readable storage medium. In the alternative, the storage medium may be integral to the processor. The processor and the storage medium may reside in an ASIC. The ASIC may reside in a user terminal, camera, or other device. In the alternative, the processor and the storage medium may reside as discrete components in a user terminal, camera, or other device.

Headings are included herein for reference and to aid in locating various sections. These headings are not intended to limit the scope of the concepts described with respect thereto. Such concepts may have applicability throughout the entire specification.

The previous description of the disclosed implementations is provided to enable any person skilled in the art to make or use the present invention. Various modifications to these implementations will be readily apparent to those skilled in the art, and the generic principles defined herein may be applied to other implementations without departing from the spirit or scope of the invention. Thus, the present invention is not intended to be limited to the implementations shown herein but is to be accorded the widest scope consistent with the principles and novel features disclosed herein.

1. An electronic system for clock correction comprising:
a first correction module, configured to modify samples of a first clock, where the first clock is associated with a first target frequency and has a first actual frequency, so that a difference between the first actual frequency and the first target frequency is reduced; and
a second correction module, configured to modify samples of a second clock, wherein the second clock is associated with a second target frequency and has a second actual frequency, based on the modifications of the first correction module, such that a difference between the second actual frequency and the second target frequency is reduced.

2. The electronic system of claim 1, wherein the modifications of the first correction module do not depend on the ratio of the first and second target frequencies.

3. The electronic system of claim 1, wherein the modifications of the second correction module depend at least in part on the ratio of the first and second target frequencies.

4. The electronic system of claim 1, wherein the modifications of the second correction module comprise insertions, skips, or both insertions and skips.

5. The electronic system of claim 1, wherein the first correction module comprises a resampling filter.

6. The electronic system of claim 1, wherein at least one of the first and second correction modules comprises a processor executing software.

7. The electronic system of claim 1, wherein to modify samples of a second clock comprises determining if a number of modified samples from the first clock is an integer multiple of a modification threshold, and if so, to insert or skip samples from the second clock.

8. The electronic system of claim 7, wherein the modification threshold is determined in part by a number of states in a digital circuit.

9. The electronic system of claim 8, wherein the ratio of the frequency of the first clock to the frequency of the second clock is P/Q, where P and Q are the smallest positive integers capable of expressing the ratio, and at least Q states of the digital circuit perform modifications.

10. An electronic system for clock correction comprising:
a first and second series of means for indicating a clock cycle;
a first means for correction configured to modify the first series of cycle indication means such that a difference between a first actual frequency and a first target frequency is reduced; and
a second means for correction configured to modify the second series of cycle indication means such that a difference between a second actual frequency and a second target frequency is reduced.

11. The electronic system of claim 10, wherein the cycle indication means comprises clock samples.

12. The electronic system of claim 10, wherein the first correction means' modifications do not depend on the ratio of the first and second target frequencies.

13. The electronic system of claim 10, wherein the second correction means' modifications depend at least in part on the ratio of the first and second target frequencies.

14. The electronic system of claim 10, wherein the second correction means' modifications comprise insertions, skips, or both insertions and skips.

15. The electronic system of claim 10, wherein the first correction means comprises a resampling filter.

16. The electronic system of claim 10, wherein at least one of the first and second correction means comprises a processor executing software.

17. The electronic system of claim 10, wherein to modify the second series of cycle indication means comprises means for determining if a number of modifications of the first series of cycle indication means by the first correction means is an integer multiple of a modification threshold, and if so, inserting or skipping cycle indication means in the second series.

18. The electronic system of claim 17, wherein the modification threshold is determined in part by a number of states in a digital circuit.

19. The electronic system of claim 18, wherein the ratio of the frequency of the first clock to the frequency of the second clock is P/Q, where P and Q are the smallest positive integers capable of expressing the ratio, and at least Q states of the digital circuit perform modifications.

20. A method for correcting a second clock based on the corrections of a first clock comprising:
at least one electronic device:
determining, on the at least one electronic device, if the number of modified samples from the first clock is an integer multiple of a modification threshold, and if so, modifying the second clock.

21. The method of claim 20, wherein the modification threshold is determined in part by a number of states in a digital circuit.

22. The method of claim 21, wherein the number of at least some of the digital circuit's states is determined based on the ratio of the first clock's frequency and the second clock's frequency.

23. The method of claim 22, wherein the ratio of the frequency of the first clock to the frequency of the second clock is P/Q, where P and Q are the smallest positive integers capable of expressing the ratio, and at least Q states of the digital circuit perform modifications.

24. The method of claim 20, wherein the number of modified samples from the first clock does not depend on the ratio of the target frequency of the first clock and the target frequency of the second clock.

25. The method of claim 20, wherein the modified samples comprise insertions, skips, or both insertions and skips.

26. The method of claim 20, wherein the corrections of the first clock are generated by a resampling filter.

27. The method of claim 20, wherein the electronic device comprises a processor executing software.

28. The method of claim 20, wherein modifying the second clock comprises inserting or skipping samples.

29. A computer-readable storage medium in communication with a computer processor comprising a computer program configured to perform a process comprising:
determining if the number of modified samples from a first clock is an integer multiple of a modification threshold, and if so, modifying a second clock.

30. The computer-readable storage medium of claim 29, wherein the modification threshold is determined in part by a number of states in a finite state machine.

31. The computer-readable medium of claim 30, wherein the number of at least some of the finite state machine's states is determined based on the ratio of the first clock's frequency and the second clock's frequency.

32. The computer-readable storage medium of claim 31, wherein the ratio of the frequency of the first clock to the frequency of the second clock is P/Q, where P and Q are the smallest positive integers capable of expressing the ratio, and at least Q states of the finite state machine perform modifications.

33. The computer-readable storage medium of claim 29, wherein the number of modified samples from the first clock does not depend on the ratio of the target frequency of the first clock and the target frequency of the second clock.

34. The computer-readable storage medium of claim 29, wherein the modified samples comprise insertions, skips, or both insertions and skips.

35. The computer-readable storage medium of claim 29, wherein the corrections of the first clock are generated by a resampling filter.

36. The computer-readable storage medium of claim 29 wherein modifying the second clock comprises inserting or skipping samples.
